(19) United States
(12) Patent Application Publication
(10) Pub. No.: US 2025/0215548 A1
(43) Pub. Date: Jul. 3, 2025

(54) MULTI-METAL OXIDE COATINGS, RELATED DEVICES AND METHODS

(71) Applicant: ENTEGRIS, INC., Billerica, MA (US)

(72) Inventors: Baosheng Sang, North Billerica, MA (US); Nilesh Gunda, North Chelmsford, MA (US); Samuel J. Angeloni, Plainville, MA (US)

(21) Appl. No.: 19/002,615

(22) Filed: Dec. 26, 2024

Related U.S. Application Data
(60) Provisional application No. 63/617,296, filed on Jan. 3, 2024.

(51) Int. Cl. C23C 14/00; C01F 17/34; C23C 14/35; C23C 14/58; H01J 37/32

(52) U.S. Cl. CPC C23C 14/0084; C01F 17/34; C23C 14/352; C23C 14/5846; H01J 37/32495; H01J 2237/334

(57) ABSTRACT

Multi-metal oxide coatings, and related devices and related methods are provided, among other things. A device comprises a substrate, and a coating on the substrate. The coating comprises a multi-metal oxide. The multi-metal oxide comprises a first species and a second species. A concentration of at least one of the first species, the second species, or any combination thereof, varies through a thickness of the coating. The device can be a component used in a semiconductor manufacturing process.

### CROSS-REFERENCE TO RELATED APPLICATION

This application claims priority to and the benefit of U.S. Provisional Application No. 63/617,296 filed on Jan. 3, 2024, which is incorporated herein by reference in its entirety for all purposes.

### FIELD

The present disclosure relates to multi-metal oxide coatings, devices including multi-metal oxide coatings, and methods for forming multi-metal oxide coatings.

### BACKGROUND

Devices and their components degrade over time from use in semiconductor fabrication processes.

### SUMMARY

Some embodiments relate to a device comprising a substrate; and a coating disposed on the substrate, wherein the coating comprises a multi-metal oxide, wherein the multi-metal oxide comprises a first species and a second species, and wherein a concentration of at least one of the first species, the second species, or any combination thereof, varies through a thickness of the coating.

Some embodiments relate to a device comprising a substrate; a first coating; and a second coating; wherein the first coating is located between the substrate and the second coating; wherein the first coating comprises a first multi-metal oxide; wherein the second coating comprises a second multi-metal oxide; wherein the second multi-metal oxide is different from the first multi-metal oxide.

Some embodiments relate to a method comprising sputtering a first metal species from a first target; sputtering a second metal species from a second target; and depositing at least one of the first metal species, the second metal species, or any combination thereof, to form a multi-metal oxide film on a substrate, wherein a ratio of the first metal species, to a sum of the first metal species and the second metal species ranges from 0.3 to 0.85.

Some embodiments relate to a method comprising sputtering a first metal species from a first target; sputtering a second metal species from a second target; and depositing at least one of the first metal species, the second metal species, or any combination thereof, to form a multi-metal oxide film on a substrate, wherein a ratio of the first metal species, to a sum of the first metal species and the second metal species, varies through a thickness of the multi-metal oxide film.

### DRAWINGS

Some embodiments of the disclosure are herein described, by way of example only, with reference to the accompanying drawings. With specific reference now to the drawings in detail, it is stressed that the embodiments shown are by way of example and for purposes of illustrative discussion of embodiments of the disclosure. In this regard, the description taken with the drawings makes apparent to those skilled in the art how embodiments of the disclosure may be practiced.

FIG. 1 is a schematic cross-sectional view of a coating on a substrate according to various embodiments.

FIG. 2 is a flowchart of a method for forming a coating on a substrate, according to various embodiments.

FIG. 3 is a schematic showing the formation of a coating on a substrate according to the method of FIG. 1.

FIG. 4 shows an EDS spectrum of a YAOF coating in accordance with an embodiment.

FIG. 5 is a chart showing Y/(Y+Al) ratio as a function of a target power ratio at both high and low deposition pressures.

FIG. 6 shows the XRD pattern of a YAO coating having a Y/(Y+Al) ratio of 0.45.

While the disclosure is amenable to various modifications and alternative forms, specifics thereof are shown by way of example in the drawings and will be described in detail below. It is to be understood, however, that the intention is not to limit the disclosure to the embodiment(s) described. On the contrary, the disclosure is intended to cover all modifications, equivalents, and alternatives falling within the scope of the disclosure as defined by the appended claims.

### DETAILED DESCRIPTION

Among those benefits and improvements that have been disclosed, other objects and advantages of this disclosure will become apparent from the following description taken in conjunction with the accompanying figures. Detailed embodiments of the present disclosure are disclosed herein; however, it is to be understood that the disclosed embodiments are merely illustrative of the disclosure that may be embodied in various forms. In addition, each of the examples given regarding the various embodiments of the disclosure which are intended to be illustrative, and not restrictive.

Any prior patents and publications referenced herein are incorporated by reference in their entireties.

Throughout the specification and claims, the following terms take the meanings explicitly associated herein, unless the context clearly dictates otherwise. The phrases “in one embodiment,” “in an embodiment,” and “in some embodiments” as used herein do not necessarily refer to the same embodiment(s), though it may. Furthermore, the phrases “in another embodiment” and “in some other embodiments” as used herein do not necessarily refer to a different embodiment, although it may. All embodiments of the disclosure are intended to be combinable without departing from the scope or spirit of the disclosure.

As used herein, the term “based on” is not exclusive and allows for being based on additional factors not described, unless the context clearly dictates otherwise. In addition, throughout the specification, the meaning of “a,” “an,” and “the” include plural references. The meaning of “in” includes “in” and “on.”

As used throughout this disclosure, concentration is defined as a weight percentage based on a total weight of a coating area or based on a total weight of the coating. Concentration of the various species found in a coating can be determined by ray spectroscopy (EDS).

Some embodiments relate to a coating including a multi-metal oxide (multi-metal oxide coating).

In some embodiments, the multi-metal oxide of the multi-metal oxide coating comprises at least two metals in the form of an oxide. In some embodiments, the multi-metal oxide comprises a metal-oxy-fluoride. In some embodiments, the multi-metal oxide includes a metal oxide and a metal-oxy-fluoride. In some embodiments, the multi-metal oxide includes an amorphous multi-metal oxide in which at least a majority (greater than 50%) of the multi-metal oxide is in an amorphous form.

In some embodiments, a concentration of at least one species of the coating varies through a thickness of the coating (e.g., a gradient coating). In some embodiments, coatings with greater thicknesses can be achieved relative to conventional coatings and/or coatings prepared by conventional processes. In some embodiments, the coatings exhibit improved temperature stability. In some embodiments, the coatings reduce coating stress and/or minimize interfaces with different coefficients of thermal expansion.

In some embodiments, the multi-metal oxide comprises a first species and a second species. In some embodiments, the first species and the second species are different. In some embodiments, the multi-metal oxide comprises more than the first species and the second species. For example, in some embodiments, the multi-metal oxide further comprises a third species, a fourth species, a fifth species, a sixth species, a seventh species, an eighth species, a ninth species, a tenth species, or more than ten species, up to one-hundred species. It will be appreciated that, when more than two species are present in the multi-metal oxide, the species may be same or different and may comprise any one or more of the examples of the first species and/or second species disclosed herein, without departing from the scope of this disclosure.

In some embodiments, the first species comprises at least one of an alkali metal, an alkaline earth metal, a transition metal, a post-transition metal, or any combination thereof. In some embodiments, the first species comprises at least one of a lithium, a sodium, a potassium, a rubidium, a cesium, a francium, a beryllium, a magnesium, a calcium, a strontium, a barium, a radium, a scandium, a titanium, a vanadium, a chromium, a manganese, an iron, a cobalt, a nickel, a copper, a zinc, a yttrium, a zirconium, a niobium, a molybdenum, a technetium, a ruthenium, a rhodium, a palladium, a silver, a cadmium, a hafnium, a tantalum, a tungsten, a rhenium, an osmium, an iridium, a platinum, a gold, a mercury, an aluminum, a gallium, an indium, tin, a thallium, a lead, a bismuth, a polonium, or any combination thereof. In some embodiments, the first species is yttrium.

In some embodiments, the second species comprises at least one of an alkali metal, an alkaline earth metal, a transition metal, post-transition metal, or any combination thereof. In some embodiments, the second species comprises at least one of a lithium, a sodium, a potassium, a rubidium, a cesium, a francium, a beryllium, a magnesium, a calcium, a strontium, a barium, a radium, a scandium, a titanium, a vanadium, a chromium, a manganese, an iron, a cobalt, a nickel, a copper, a zinc, a yttrium, a zirconium, a niobium, a molybdenum, a technetium, a ruthenium, a rhodium, a palladium, a silver, a cadmium, a hafnium, a tantalum, a tungsten, a rhenium, an osmium, an iridium, a platinum, a gold, a mercury, an aluminum, a gallium, an indium, tin, a thallium, a lead, a bismuth, a polonium, or any combination thereof. In some embodiments, the second species is aluminum.

In some embodiments, the multi-metal oxide may include oxides of any one or more of the first species and the second species. For example, the multi-metal oxide can include two or more of the following: an aluminum oxide, a silicon oxide, an yttrium oxide, a magnesium oxide, a calcium oxide, a zirconium oxide, a hafnium oxide, a boron oxide, or any combination thereof. It will be appreciated that at least one multi-metal oxide can be fluorinated.

In some embodiments, the coating further comprises a third species. In some embodiments, the third species comprises a fluorine species. In some embodiments, the fluorine species is present on all vapor-exposed surfaces, wherein vapor exposed surfaces comprise surfaces exposed to a reactive fluorine-containing vapor. In some embodiments, for example, the coating comprises a reaction product of a reactive fluorine-containing vapor and at least one of the first species, the second species, or any combination thereof. The reaction product may be an oxyfluoride. In some embodiments, when the coating is exposed to the reactive fluorine-containing vapor, the reactive fluorine-containing vapor reacts with a surface of the coating. In some embodiments, when the coating is exposed to the reactive fluorine-containing vapor, the reactive fluorine-containing vapor diffuses through from the surface of the coating to a depth beneath the surface of the coating, where the reactive fluorine-containing vapor reacts with at least one of the first species, the second species, or any combination thereof. In some embodiments, the depth and concentration of the reaction product varies through a thickness of the coating. In some embodiments, the depth and/or concentration of the reaction product may vary with the duration of exposure, conditions of exposure, among other factors. In some embodiments, the concentration of the fluorine species in the multi-metal oxide coating varies through the thickness of the coating.

In some embodiments, the reactive fluorine-containing vapor comprises a molecular fluorine source vapor, which may be derived from a liquid or a solid. In some embodiments, a molecular fluorine vapor source may be liquid or solid at room temperature but vaporizes at the process temperatures disclosed herein. In some embodiments, the molecular fluorine is not ionic, substantially nonionic, and/or not processed (e.g., by adding energy other than heat) to form a plasma.

In some embodiments, the reactive fluorine-containing vapor is derived from a source including at least one of a fluorinated organic compound, a perfluorinated organic compound, or any combination thereof. In some embodiments, for example, the reactive fluorine-containing vapor is derived from a source including at least one of a fluorinated alkane, a perfluorinated alkane, a fluorinated alkene, a perfluorinated alkene, or any combination thereof, wherein any one or more of which may be linear or branched. In some embodiments, the reactive fluorine-containing vapor is derived from a source comprising at least one of CF₄, C₂F₄, C₃F₆, C₄F₈, CHF₃, C₂H₂F₂, C₂F₆, HF, CH₃F, or any combination thereof.

In some embodiments, the reactive fluorine-containing vapor is derived from a source including a fluorinated polymer. In some embodiments, the reactive fluorine-containing vapor is derived from a source including a non-gaseous fluorinated polymer (e.g., a solid or a liquid phase fluorinated polymer). In some embodiments, the fluorinated polymer from which the vapor is derived comprises a homopolymer or a copolymer. In some embodiments, the fluorinated polymer comprises a copolymer of at least one fluoro-olefin monomer and optionally at least one non-fluorinated co-monomer. The fluorinated polymer can be partially or fully or can include non-fluorine halogen atoms, such as, for example and without limitation, chlorine. Examples of use fluoropolymers include, without limitation, at least one of the following: polymerized perfluoroalkylethylene having a C₁-C₁₀ perfluoroalkyl group, polytetrafluoroethylene (PTFE), tetrafluoroethylene/perfluoro (alkyl vinyl ether) copolymer (PFA), tetrafluoroethylene/hexafluoropropylene copolymer (FEP), tetrafluoroethylene/perfluoro (alkyl alkenyl ether)/hexafluoropropylene copolymer (EPA), polyhexafluoropropylene, ethylene/tetrafluoroethylene copolymer (ETFE), poly trifluoroethylene, polyvinylidene fluoride (PVDF), polyvinyl fluoride (PVF), polychlorotrifluoroethylene (PCTFE), ethylene/chlorotrifluoroethylene copolymer (ECTFE), or any combination thereof.

In some embodiments, the multi-metal oxide in the multi-metal oxide coating has a percent crystallinity of 0% (e.g., entirely amorphous) to 100% (e.g., entirely crystalline), or any range or subrange between 0% and 100%. In some embodiments, the percent crystallinity of the multi-metal oxide is 0% to 90%, 0% to 80%, 0% to 70%, 0% to 60%, 0% to 50%, 0% to 40%, 0% to 30%, 0% to 20%, 0% to 10%, 10% to 100%, 20%, to 100%, 30% to 100%, 40% to 100%, 50% to 100%, 60% to 100%, 70% to 100%, 80% to 100%, or 90% to 100%. Percent crystallinity can be determined by X-ray diffraction (XRD).

In some embodiments, the multi-metal oxide coating has a thickness of 1 μm to 25 μm, or any range or subrange between 1 μm and 25 μm. In some embodiments, the thickness is in a range of 1 μm to 20 μm, 1 μm to 15 μm, 1 μm to 10 μm, 1 μm to 5 μm, 5 μm to 25 μm, 10 μm to 25 μm, 15 μm to 25 μm, or 20 μm to 25 μm.

In some embodiments, a concentration of at least one of the first species, the second species, or any combination thereof, can vary through a thickness of the coating. As used throughout this disclosure, concentration is defined as a weight percentage based on a total weight of a coating area or based on a total weight of the coating. The concentration is determined by EDS. In some embodiments, the concentration of only one of the first species or the second species varies through the thickness of the coating. In some embodiments, the concentration of both the first species and the second species varies through the thickness of the coating. In some embodiments, the concentration of the first species varies, through a thickness of the coating, between 0% to 100%, 0% to 90%, 0% to 80%, 0% to 70%, 0% to 60%, 0% to 50%, 0% to 40%, 0% to 30%, 0% to 20%, 0% to 10%, 10% to 100%, 20% to 100%, 30% to 100%, 40% to 100%, 50% to 100%, 60% to 100%, 70% to 100%, 80% to 100%, 90% to 100%, or any range or subrange between 0% and 100%. For example, in some embodiments, through a thickness of the coating, the concentration of the first species in some areas is 0% and in other areas is 100% (e.g., when the concentration of the first species is 0% to 100%).

In some embodiments, the concentration of the second species varies, through a thickness of the coating, between 0% to 100%, 0% to 90%, 0% to 80%, 0% to 70%, 0% to 60%, 0% to 50%, 0% to 40%, 0% to 30%, 0% to 20%, 0% to 10%, 10% to 100%, 20% to 100%, 30% to 100%, 40% to 100%, 50% to 100%, 60% to 100%, 70% to 100%, 80% to 100%, 90% to 100%, or any range or subrange between 0% and 100%. For example, in some embodiments, through a thickness of the coating, the concentration of the second species in some areas is 0% and in other areas is 100% (e.g., when the concentration of the first species is 0% to 100%). In some embodiments, the concentration is a weight percentage based on a total weight of a coating area or based on a total weight of the coating.

In some embodiments, a ratio (X/(X+Y)) of the concentration of the first metal species X, to a sum of the concentrations of the first metal species X and the second metal species Y, ranges from 0.3 to 0.85. In some embodiments, a ratio (X/(X+Y)) of the concentration of a first metal species X, to a sum of the first metal species and the second metal species (X+Y) can be any range or subrange between 0.3 to 0.85. In some embodiments, the ratio is a ratio in a range of 0.3 to 0.6, 0.3 to 0.5, 0.3 to 0.4, 0.4 to 0.7, 0.5 to 0.85, or 0.6 to 0.85.

In some embodiments, when the coating is exposed to a corrosive component, a difference in a thickness of the coating, before and after being exposed, is 1% or less. The corrosive component may comprise any corrosive substance, in either a liquid, gas, and/or vapor form. For example, in some embodiments, the corrosive component can include a halogen-containing gas such as a fluorine or chlorine-containing gas. In some embodiments, a difference in a thickness of the coating, before and after exposure to the halogen containing gas, can range from 0.01% to 1%, 0.1% to 1%, 0.2% to 1%, 0.3% to 1%, 0.4% to 1%, 0.5% to 1%, 0.6% to 1%, 0.7% to 1%, 0.8% to 1%, 0.9% to 1%, 0.01% to 0.9%, 0.01% to 0.8%, 0.01% to 0.7%, 0.01% to 0.6%, 0.01% to 0.5%, 0.01% to 0.4%, 0.01% to 0.3%, 0.01% to 0.2%, 0.01% to 0.1%, or 0.01% to 0.05%.

In some embodiments, when the coating is exposed to a plasma a difference in a thickness of the coating, before and after being exposed, is 1% or less. Exemplary plasmas include those plasmas used in the manufacture of semiconductor devices. Exemplary plasmas can include hydrogen, oxygen, nitrogen, argon, or combinations thereof. Plasmas can include additional components such fluorine or chlorine containing components such as, for example, NF₃, Cl₂, or BCl₃. In one embodiment, the plasma is hydrogen plasma. In some embodiments, a difference in a thickness of the coating, before and after being exposed to hydrogen plasma, can range from 0.01% to 1%, 0.1% to 1%, 0.2% to 1%, 0.3% to 1%, 0.4% to 1%, 0.5% to 1%, 0.6% to 1%, 0.7% to 1%, 0.8% to 1%, 0.9% to 1%, 0.01% to 0.9%, 0.01% to 0.8%, 0.01% to 0.7%, 0.01% to 0.6%, 0.01% to 0.5%, 0.01% to 0.4%, 0.01% to 0.3%, 0.01% to 0.2%, 0.01% to 0.1%, or 0.01% to 0.05%.

According to the various embodiments described herein, the multi-metal oxide coating can include at least one of an yttrium aluminum oxide (e.g., YAO, Y₃Al₅O₁₂, YAlO₃, Y₄Al₂O₉), yttrium aluminum oxyfluoride (YAOF), or any combination thereof.

In some embodiments, the coating can be a multi-layer coating including at least a first coating layer and a second coating layer. In some embodiments, the first coating layer is located between the substrate and the second coating layer. In some embodiments, the first coating layer directly contacts the substrate. In some embodiments, the first coating layer directly contacts the second coating layer. In some embodiments, an intervening layer is located between the first coating layer and the substrate. In some embodiments, an intervening layer is located between the first coating layer and the second coating layer. In some embodiments, the first coating layer covers the substrate in its entirety. In some embodiments, the second coating layer covers the substrate in its entirety. In some embodiments, the first coating layer covers a portion of the substrate. In some embodiments, the second coating layer covers a portion of the substrate. It will further be appreciated that additional coating layers in addition to the first and second coating layers may be used herein without departing from the scope of this disclosure.

Each of the first and second coating layers includes a coating, as disclosed herein according to the various embodiments. The first and/or second coating layer can include any one or more of the coatings disclosed according to the various embodiments. The first coating layer can include a first coating and the second layer can include a second coating. In some embodiments the first coating of the first coating layer is the same as the second coating of the second coating layer and in other embodiments, the second coating of the second coating layer is different from a first coating of the first coating layer. Additional coating layers may comprise any one or more of the coatings disclosed herein, without departing from the scope of this disclosure.

In one embodiment, the first coating and/or the second coating can include alumina or yttrium. For example, the first coating can include alumina and the second coating can include yttria. At least one of the first and second coatings can be fluorinated. In some embodiments, the first coating can include alumina and the second coating can include a multi-metal oxide. The multi-metal oxide can be fluorinated. In on example, the second coating can include an yttrium aluminum oxide (e.g., YAO, Y₃Al₅O₁₂, YAlO₃, Y₄Al₂O₉), yttrium aluminum oxyfluoride (YAOF), or any combination thereof.

In some embodiments, the first coating of the first layer comprises a first multi-metal oxide including a first metal species and a second metal species different from the first metal species. In some embodiments, a concentration of the at least one of the first metal species, the second metal species, or any combination thereof, varies through a thickness of the first coating layer. In some embodiments, the first coating further comprises a fluorine species.

In some embodiments, the second coating of the second coating layer comprises a second multi-metal oxide. In some embodiments, the second multi-metal oxide can include a third and a fourth species that is the same species as the first and second species of the first multi-metal oxide. In other embodiments, the second multi-metal oxide comprises a third and a fourth species that are different than the first and second species. In some embodiments, a concentration of at least one of the third species, the fourth species, or any combination thereof, varies through a thickness of the second coating. In some embodiments, the second coating further comprises a fluorine species.

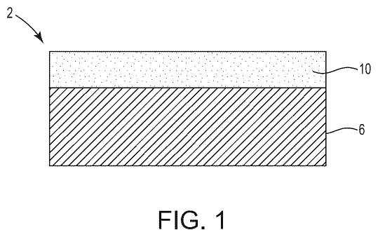

Some embodiments relate to a device including a multi-metal oxide coating as described herein according to the various embodiments. The device and/or the component(s) of the device includes a substrate. FIG. 1 is a schematic cross sectional view of a device 2 having a substrate 6 including a multi-metal oxide coating 10 disposed thereon, as described herein according to the various embodiments.

The device can include one or more components used in a semiconductor manufacturing process step. For example, in some embodiments, the device can be a process chamber in which a process step of a semiconductor manufacturing process is performed (e.g., an etch chamber and/or etch chamber components). In some embodiments, the substrate can include at least one of a metal (e.g. aluminum or copper), a metal alloy (e.g. stainless steel), a ceramic (e.g. alumina or zirconia), a polymeric substrate (e.g., polyethylene terephthalate, polyimide), quartz, glass, a silicon-containing material, a carbon-containing material, a dielectric material, a semiconductor substrates (e.g., gallium arsenide, indium phosphide), ceramic-coated substrates, plastic substrates (e.g., polycarbonate, polypropylene), metal oxide substrates (e.g., indium tin oxide), or any combination thereof. In some embodiments the substrate comprises at least one of stainless steel, quartz, alumina, a ceramic, a metal alloy, or any combination thereof.

In some embodiments, a multi-metal oxide coating as described herein according to the various embodiments is disposed on a surface of the substrate. In some embodiments, the coating covers the substrate in its entirety. In some embodiments, the coating covers a portion of the substrate. In some embodiments, the coating directly contacts the substrate. In some embodiments, an intervening layer is located between the coating and the substrate. The coating may comprise any one or more of the coatings disclosed herein. In some embodiments, the multi-metal oxide comprises YAO, wherein the first species comprises yttrium and wherein the second species comprises aluminum. In some embodiments, the multi-metal oxide comprises at least one of an yttrium aluminum oxide (e.g., YAO, Y₃Al₅O₁₂, YAlO₃, Y₄Al₂O₉), yttrium aluminum oxyfluoride (YAOF), an yttrium aluminum garnet (Y₃Al₅O₁₂, YAG), a monoclinic yttrium aluminate (Y₄Al₂O₉, YAM), an yttrium aluminum perovskite (YAlO₃, YAP), or any combination thereof. In an exemplary embodiment, the multi-metal coating includes yttrium aluminum oxyfluoride.

In some embodiments, the multi-metal oxide coating has a thickness (t) of 1 μm to 25 μm, or any range or subrange between 1 μm and 25 μm. In some embodiments, the thickness is in a range of 1 μm to 20 μm, 1 μm to 15 μm, 1 μm to 10 μm, 1 μm to 5 μm, 5 μm to 25 μm, 10 μm to 25 μm, 15 μm to 25 μm, or 20 μm to 25 μm.

In some embodiments, a concentration of at least one of the first species, the second species, or any combination thereof, can vary through a thickness of the coating. In some embodiments, the concentration of only one of the first species or the second species varies through the thickness of the coating. In some embodiments, the concentration of both the first species and the second species varies through the thickness of the coating. In some embodiments, the concentration of the first species varies, through a thickness of the coating, between 0% to 100%, 0% to 90%, 0% to 80%, 0% to 70%, 0% to 60%, 0% to 50%, 0% to 40%, 0% to 30%, 0% to 20%, 0% to 10%, 10% to 100%, 20% to 100%, 30% to 100%, 40% to 100%, 50% to 100%, 60% to 100%, 70% to 100%, 80% to 100%, 90% to 100%, or any range or subrange between 0% and 100%. For example, in some embodiments, through a thickness of the coating, the concentration of the first species in some areas is 0% and in other areas is 100% (e.g., when the concentration of the first species is 0% to 100%). In some embodiments, the concentration of the first species decreases in a direction from an outer surface of the coating to an inner surface of the coating relative to a surface of a substrate on which the coating is disposed.

In some embodiments, the concentration of the second species varies, through a thickness of the coating, between 0% to 100%, 0% to 90%, 0% to 80%, 0% to 70%, 0% to 60%, 0% to 50%, 0% to 40%, 0% to 30%, 0% to 20%, 0% to 10%, 10% to 100%, 20% to 100%, 30% to 100%, 40% to 100%, 50% to 100%, 60% to 100%, 70% to 100%, 80% to 100%, 90% to 100%, or any range or subrange between 0% and 100%. For example, in some embodiments, through a thickness of the coating, the concentration of the second species in some areas is 0% and in other areas is 100% (e.g., when the concentration of the first species is 0% to 100%). Concentration is defined as a weight percentage based on a total weight of a coating area or based on a total weight of the coating as determined by EDS. In some embodiments, the concentration of the second species decreases in a direction from an outer surface of the coating to an inner surface of the coating relative to a surface of a substrate on which the coating is disposed.

In some embodiments, a ratio (X/(X+Y)) of the concentration of the first metal species, to a sum of the concentrations of the first metal species and the second metal species, is 0.3 to 0.85. In some embodiments, a ratio (X/(X+Y)) of the first metal species X, to a sum of the first metal species and the second metal species (X+Y) can range from 0.3 to 0.85, or include any range or subrange between 0.3 to 0.85. In some embodiments, the ratio (X/(X+Y)) ranges from 0.3 to 0.6, 0.3 to 0.5, 0.3 to 0.4, 0.4 to 0.7, 0.5 to 0.85, or 0.6 to 0.85. In some embodiments, the ratio (X/(X+Y)) decreases in a direction from an outer surface of the coating to an inner surface of the coating relative to a surface of a substrate on which the coating is disposed.

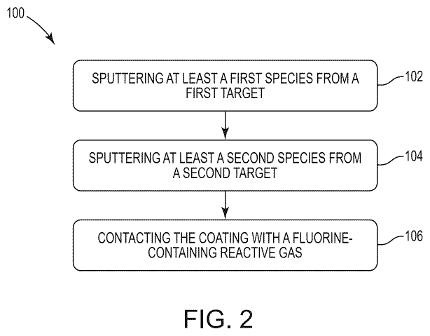

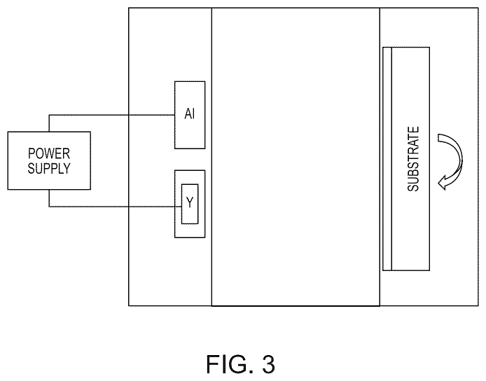

FIG. 2 is a flowchart of a method for forming a multi-metal oxide coating, according to some embodiments. The method may be useful for forming any one or more of the coatings disclosed herein. FIG. 3 shows a schematic of the formation of a multi-metal oxide coating following the method of FIG. 2 as described below in more detail.

As shown in FIG. 2, in some embodiments, the method for forming the multi-metal oxide coating on a substrate includes: sputtering 102 a first species from a first target; sputtering 104 a second species from a second target; depositing 106 at least one of the first species, the second species, or any combination thereof, to form a coating on a substrate; and contacting 108 the coating with a fluorine-containing reactive gas to at least partially fluorinate the coating. The oxide coating may comprise any one or more of the coatings disclosed herein. For example, in some embodiments, the coating is a multi-metal oxide metal oxide coating. In some embodiments, at least 50% of the multi-metal oxide in the multi-metal oxide coating is amorphous. In some embodiments, the first target comprises yttrium and second target comprises aluminum and coating that is formed is an yttrium aluminum oxide film wherein when fluorinated, comprises yttrium aluminum oxyfluoride (YAOF). In some cases, the multi-metal oxide coating is a multi-layer multi-metal oxide coating

At steps 102 and 104, the method comprises sputtering the first species from the first target and sputtering the second species from the second target, respectively. In some embodiments, the sputtering of the first species from the first target comprises applying a power to the first target. In some embodiments, the sputtering of the second species from the second target comprises applying a power to the second target. Steps 102, 104 of sputtering 102 the first species and the second species from the first target and the second target, respectfully, can be performed in the presence of argon or oxygen. In some embodiments, the sputtering of the first and/or second species comprises applying a power to the first target and the second target using a single power supply, as shown in FIG. 3. In some cases, the power is supplied to the first and second target using a dual magnetron power supply. In some embodiments a different target power can be applied to each individual target, which facilitates reactive sputtering of the first and second metal targets in the presence of oxygen to form a multi-metal oxide coating on the substrate. The target power applied to each of the first and second target can also be the same or different. In some embodiments, the power is applied to the first target and the second target, from the single power supply, at different times. In some embodiments, the power is applied to the first target and the second target, from the single power supply, at the same time.

The power applied to each of the first target and the second target can be varied. The amount of time for which the power is applied to the first and/or second target can also be varied. In some embodiments, the power applied to the first target and the second target can be varied such that a ratio (X/(X+Y)) of the first metal species X to the sum of the first and second metal species (X+Y) in the multi-metal oxide coating is varied. The power applied to the first target and the second target can be varied to form a multi-metal oxide coating having a ratio (X/(X+Y)) of a first metal species X to the sum of the first metal species and a second metal species (X+Y) ranging from 0.3 to 0.85, or any range or subrange between 0.3 to 0.85. In some embodiments, the ratio (X/(X+Y)) in the multi-metal oxide coating can range from 0.3 to 0.6, 0.3 to 0.5, 0.3 to 0.4, 0.4 to 0.7, 0.5 to 0.85, or 0.6 to 0.85. In some embodiments, the power and amount of time the power applied in each of the first and second sputtering steps 102, 104 can be varied to alter the ratio (X/(X+Y)) such that the ratio (X/(X+Y)) decreases in a direction from an outer surface of the coating to a surface of the substrate.

It will be appreciated by those of skill in the art that in embodiments in which the multi-metal oxide coating is present as a layer of a multi-layer coating applied to the substrate, the power and amount of time the power is applied to the first and second targets can be varied to vary the ratio (X/(X+Y)) in the multi-metal coating layer of the multilayer coating.

At step 106, the multi-metal oxide coating is exposed or contacted with a fluorine-containing reactive gas for an amount of time sufficient to fluorinate at least a portion of the multi-metal oxide coating or coating layer. In some embodiments, step 106 includes exposing the multi-metal oxide to the fluorine-containing reactive gas. In some embodiments, step 106 can include introducing, supplying, pumping, drawing (e.g., via vacuum), injecting, flowing, or otherwise providing the fluorine-containing reactive gas such that the fluorine-containing reactive gas is brought into immediate or close proximity to the multi-metal oxide coating or, in some cases, direct physical contact with the multi-metal oxide coating. In some embodiments, step 106 proceeds for a duration of one second to seven days, or any range or subrange between one second and seven days.

In some embodiments, when the multi-metal oxide coating is exposed to a hydrogen component, a difference in a thickness of the multi-metal oxide coating, before and after being exposed, is 1% or less.

The method 100 can be used to form a multi-metal oxide coating or a fluorinated multi-metal oxide coating, as described herein according to the various embodiments, on a surface of a process component used in a semiconductor manufacturing process. One such process component is an etch chamber or a component of an etch chamber.

### EXAMPLES

### Example 1

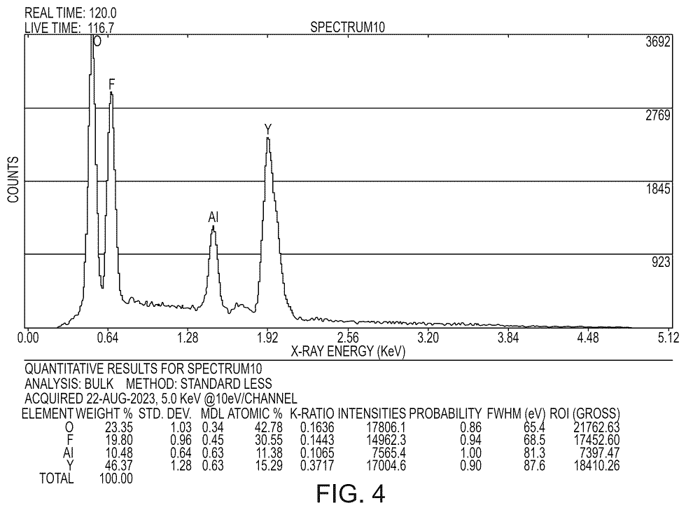

Samples were prepared by depositing a coating containing yttrium oxide and aluminum onto a substrate by reactive sputtering using a single dual magnetron sputtering (DMS) power supply coupled to both an yttrium target and an aluminum target. The ratio of power applied to each of the targets was varied to deposit an yttrium aluminum oxide (YAO) coatings having various Y/(Y+Al) ratios. The coated substrates were placed into an annealing oven and exposed to a fluorine containing atmosphere to fluorinate the coatings. FIG. 4 is a spectrum of a YAOF coating generated using Energy Dispersive X-ray spectroscopy (EDS) at 5 KeV. As can be seen from FIG. 4, a YAOF coating can have fluorine concentration of up to 30%.

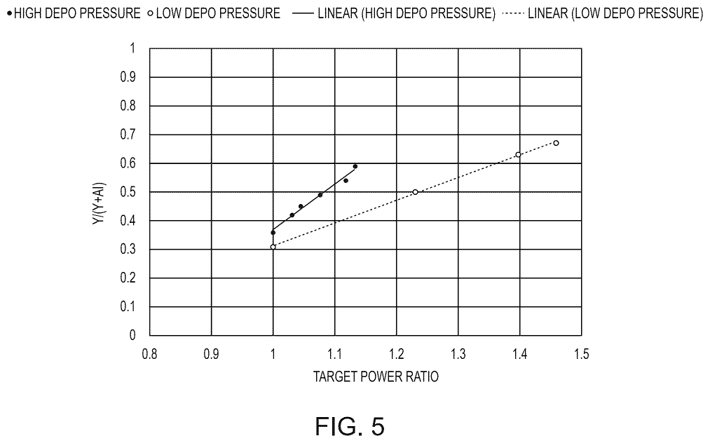

FIG. 5 shows the Y/(Y+Al) ratio as determined by EDS plotted against the target power ratio at both high a low pressures. As can be seen from the chart provided in FIG. 5 the Y/(Y+Al) ranges from 0.3 to 0.7 at low pressures. However, it was found that when the same coatings were analyzed using X-ray Fluorescence (XRF) spectroscopy, the Y/(Y+Al) was found to be about 0.15 higher than when measured using EDS.

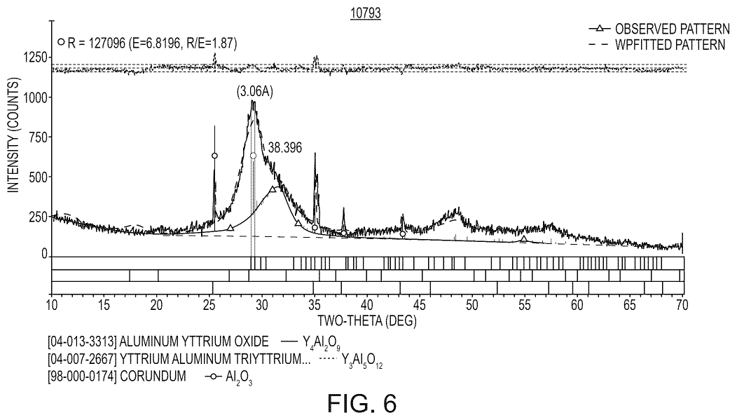

The crystalline structure of a coating including having a Y/(Y+Al) ratio of 0.45 was analyzed using X-ray diffraction (XRD). FIG. 6 shows the XRD pattern of the YAO coating having a Y/(Y+Al) ratio of 0.45. The phase analysis is presented in Table 1 below.

TABLE 1

| Phase | |
|---|---|
| Y₄Al₂O₉ (Monoclinic) | 38.3% |
| Y₃Al₅O₁₂ (Cubic) | |
| *Amorphous | 61.7% |

The XRD pattern shows that the coating has a mixture of a monoclinic phase (38.3%) and an amorphous phase (61.7%). Fluorination of such a coating is not expected to change its crystalline structure.

### Example 2

A sample including a substrate coated with a YAOF film was exposed to hydrogen plasma at 400 W for three hours. The thickness of the YAOF film was measured before and after exposure using a profilometer. No detectable difference in thickness was observed.

### Aspects

Various Aspects are described below. It is to be understood that any one or more of the features recited in the following Aspect(s) can be combined with any one or more other Aspect(s).

Aspect 1. A device comprising:
a substrate; and
a coating located on the substrate,
   wherein the coating comprises a multi-metal oxide,
      wherein the multi-metal oxide comprises a first species and a second species,
         wherein a concentration of at least one of the first species, the second species, or any combination thereof, varies through a thickness of the coating.

Aspect 2. The device according to Aspect 1, wherein the substrate comprises at least one of a stainless steel, a quartz, an alumina, a ceramic, or any combination thereof.

Aspect 3. The device according to any one of Aspects 1-2, wherein the substrate comprises at least one of at least one metal, at least one alloy, or any combination thereof.

Aspect 4. The device according to any one of Aspects 1-3, wherein the concentration of only one of the first species or the second species varies through the thickness of the coating.

Aspect 5. The device according to any one of Aspects 1-4, wherein the concentration of the first species and the second species varies through the thickness of the coating.

Aspect 6. The device according to any one of Aspects 1-5, wherein a ratio of the first species, to a sum of the first species and the second species, is 0.3 to 0.85.

Aspect 7. The device according to any one of Aspects 1-6, wherein the coating has a thickness of 1 μm to 25 μm.

Aspect 8. The device according to any one of Aspects 1-7, wherein the coating further comprises:
a third species,
   wherein a concentration of the third species varies through the thickness of the coating.

Aspect 9. The device according to Aspect 8, wherein the third species comprises a fluorine.

Aspect 10. The device according to any one of Aspects 1-9, wherein the multi-metal oxide comprises at least one of an yttrium aluminum oxide (YAO), a fluorinated yttrium aluminum oxide, an yttrium aluminum garnet (YAG), a monoclinic yttrium aluminate (YAM), an yttrium aluminum perovskite (YAP), or any combination thereof.

Aspect 11. The device according to any one of Aspects 1-10, wherein the multi-metal oxide comprises an amorphous multi-metal oxide.

Aspect 12. The device according to any one of Aspects 1-11, wherein, when the coating is exposed to a corrosive component, a difference in a thickness of the coating, before and after being exposed, 1% or less.

Aspect 13. The device according to any one of Aspects 1-12, wherein the corrosive component comprises at least one of a hydrogen, a halide, or any combination thereof.

Aspect 14. The device according to any one of Aspects 1-13, further comprising:
at least one layer comprising a metal oxide,
   wherein the at least one layer is located between the substrate and the coating, or the coating is located between the substrate and the at least one layer,
   wherein the at least one layer is different from the coating.

Aspect 15. The device according to Aspect 14, wherein the at least one layer comprises:
a first layer comprising alumina; and
a second layer comprising yttria,
   wherein the first layer is located between the substrate and the coating,
   wherein the second layer is located between the first layer and the coating.

Aspect 16. A device comprising:
a substrate;
a first coating; and
a second coating;
   wherein the first coating is located between the substrate and the second coating;
   wherein the first coating comprises a first multi-metal oxide;
   wherein the second coating comprises a second multi-metal oxide;
      wherein the second multi-metal oxide is different from the first multi-metal oxide.

Aspect 17. The device according to 16, wherein the substrate comprises at least one of a stainless steel, a quartz, an alumina, a ceramic, or any combination thereof.

Aspect 18. The device according to any one of Aspects 16-17, wherein the first multi-metal oxide comprises:
a first species; and
a second species;
   wherein a concentration of at least one of the first species, the second species, or any combination thereof, varies through a thickness of the first coating.

Aspect 19. The device according to Aspect 18, wherein a ratio of the first species, to a sum of the first species and the second species, is 0.3 to 0.85.

Aspect 20. The device according to any one of Aspects 16-19, wherein the first coating further comprises:
a fluorine species,
   wherein a concentration of the fluorine species varies through the thickness of the first coating.

Aspect 21. The device according to any one of Aspects 16-20, wherein the second multi-metal oxide comprises:
a third species; and
a fourth species;
   wherein a concentration of at least one of the third species, the fourth species, or any combination thereof, varies through a thickness of the second coating.

Aspect 22. The device according to any one of Aspects 16-21, wherein a ratio of the third species, to a sum of the third species and the fourth species, is 0.3 to 0.85.

Aspect 23. The device according to any one of Aspects 16-22, wherein the second coating further comprises:
a fluorine species,
   wherein a concentration of the fluorine species varies through the thickness of the second coating.

Aspect 24. A method comprising:
sputtering a first metal species from a first target;
sputtering a second metal species from a second target; and
depositing at least one of the first metal species, the second metal species, or any combination thereof, to form a multi-metal oxide film on a substrate,
   wherein a ratio of the first metal species, to a sum of the first metal species and the second metal species, is 0.3 to 0.85.

Aspect 25. The method according to Aspect 24, wherein the ratio of the first metal species, to the sum of the first metal species and the second metal species, varies through a thickness of the multi-metal oxide film.

Aspect 26. The method according to any one of Aspects 24-25, wherein, when the multi-metal oxide film is exposed to a hydrogen component, a difference in a thickness of the multi-metal oxide film, before and after being exposed, is 1% or less.

Aspect 27. The method according to any one of Aspects 24-26, further comprising:
supplying an oxygen component,
   wherein the step of sputtering the first metal species is performed in a presence of the oxygen component.

Aspect 28. The method according to any one of Aspects 24-27, further comprising: supplying an oxygen component,
wherein the step of sputtering the second metal species is performed in a presence of the oxygen component.

Aspect 29. The method according to any one of Aspects 24-28, further comprising applying a power to the first target and to the second target using a single power supply.

Aspect 30. The method according to any one of Aspects 24-29, further comprising applying a power to the first target and to the second target using a dual magnetron sputtering power supply.

Aspect 31. The method according to any one of Aspects 24-30, wherein the multi-metal oxide film comprises an amorphous multi-metal oxide.

Aspect 32. The method according to any one of Aspects 24-31, wherein the first target comprises yttrium, and wherein the second target comprises aluminum.

Aspect 33. The method according to any one of Aspects 24-32, wherein the multi-metal oxide film comprises an yttrium aluminum oxide film.

Aspect 34. The method according to any one of Aspects 24-33, further comprising:

contacting the multi-metal oxide film with a reactive gas comprising a fluorine component sufficient to fluorinate at least a portion of the multi-metal oxide film.

Aspect 35. The method according to any one of Aspects 24-34, wherein the substrate is a component of an etch chamber.

Aspect 36. A method comprising:
sputtering a first metal species from a first target;
sputtering a second metal species from a second target; and
depositing at least one of the first metal species, the second metal species, or any combination thereof, to form a multi-metal oxide film on a substrate,
   wherein a ratio of the first metal species, to a sum of the first metal species and the second metal species, varies through a thickness of the multi-metal oxide film.

Aspect 37. The method according to Aspect 36, wherein the ratio of the first metal species, to the sum of the first metal species and the second metal species, is 0.3 to 0.85.

Aspect 38. The method according to any one of Aspects 36-37, wherein, when the multi-metal oxide film is exposed to a hydrogen component, a difference in a thickness of the multi-metal oxide film, before and after being exposed, is 1% or less.

Aspect 39. The method according to any one of Aspects 36-38, further comprising: supplying an oxygen component,
wherein the step of sputtering the first metal species is performed in a presence of the oxygen component; and/or
wherein the step of sputtering the second metal species is performed in a presence of the oxygen component.

Aspect 40. The method according to any one of Aspects 36-39, further comprising applying a power to the first target and to the second target using a single power supply.

Aspect 41. The method according to any one of Aspects 36-40, wherein the multi-metal oxide film comprises an amorphous multi-metal oxide.

Aspect 42. The method according to any one of Aspects 36-41, wherein the first target comprises yttrium, and wherein the second target comprises aluminum.

Aspect 43. The method according to any one of Aspects 36-42, wherein the multi-metal oxide film comprises an yttrium aluminum oxide film.

Aspect 44. The method according to any one of Aspects 36-43, further comprising:
contacting the multi-metal oxide film with a reactive gas comprising a fluorine component sufficient to fluorinate at least a portion of the multi-metal oxide film.

Aspect 45. The method according to any one of Aspects 36-44, wherein the substrate is a component of an etch chamber.

The scope of this disclosure encompasses all changes, substitutions, variations, alterations, and modifications to the example embodiments described or illustrated herein that a person having ordinary skill in the art would comprehend. The scope of this disclosure is not limited to the example embodiments described or illustrated herein. Moreover, although this disclosure describes and illustrates respective embodiments herein as including particular components, elements, feature, functions, operations, or steps, any of these embodiments may include any combination or permutation of any of the components, elements, features, functions, operations, or steps described or illustrated anywhere herein that a person having ordinary skill in the art would comprehend. Furthermore, reference in the appended claims to an apparatus or system or a component of an apparatus or system being adapted to, arranged to, capable of, configured to, enabled to, operable to, or operative to perform a particular function encompasses that apparatus, system, component, whether or not it or that particular function is activated, turned on, or unlocked, as long as that apparatus, system, or component is so adapted, arranged, capable, configured, enabled, operable, or operative. Additionally, although this disclosure describes or illustrates particular embodiments as providing particular advantages, particular embodiments may provide none, some, or all of these advantages.

What is claimed is:

1. A device comprising:
a substrate; and
a coating disposed on the substrate,
wherein the coating comprises a multi-metal oxide,
wherein the multi-metal oxide comprises a first species and a second species,
wherein a concentration of at least one of the first species, the second species, or any combination thereof, varies through a thickness of the coating.

2. The device of claim 1, wherein the substrate comprises at least one of a stainless steel, a quartz, an alumina, a ceramic, or any combination thereof.

3. The device of claim 1, wherein the concentration of only one of the first species or the second species varies through the thickness of the coating.

4. The device of claim 1, wherein the concentration of the first species and the second species varies through the thickness of the coating.

5. The device of claim 1, wherein a ratio (X/(X+Y)) of the first species X, to a sum of the first species and the second species (X+Y), is 0.3 to 0.85.

6. The device of claim 1, wherein the coating has a thickness of 1 μm to 25 μm.

7. The device of claim 1, wherein the coating further comprises:
a third species,
wherein a concentration of the third species varies through the thickness of the coating.

8. The device of claim 7, wherein the third species comprises a fluorine.

9. The device of claim 1, wherein the multi-metal oxide comprises at least one of an yttrium aluminum oxide (YAO), yttrium aluminum oxyfluoride (YAOF), an yttrium aluminum garnet (YAG), a monoclinic yttrium aluminate (YAM), an yttrium aluminum perovskite (YAP), or any combination thereof.

10. The device of claim 1, wherein the multi-metal oxide comprises an amorphous multi-metal oxide.

11. The device of claim 1, wherein, when the coating is exposed to a corrosive component, a difference in a thickness of the coating, before and after being exposed, 1% or less.

12. The device of claim 11, wherein the corrosive component comprises at least one of a hydrogen, a halide, or any combination thereof.

13. The device of claim 1, further comprising:
at least one layer comprising a metal oxide,
wherein the at least one layer is located between the substrate and the coating, or the coating is located between the substrate and the at least one layer,
wherein the at least one layer is different from the coating.

14. The device of claim 13, wherein the at least one layer comprises:
a first layer comprising alumina; and
a second layer comprising yttria,
wherein the first layer is located between the substrate and the coating,
wherein the second layer is located between the first layer and the coating.

15. The device of claim 1, where in the device is a component used in a semiconductor manufacturing process.

16. A method comprising:
sputtering a first metal species from a first target;
sputtering a second metal species from a second target; and
depositing at least one of the first metal species, the second metal species, or any combination thereof, to form a multi-metal oxide film on a substrate,
wherein a ratio of the first metal species, to a sum of the first metal species and the second metal species, is 0.3 to 0.85.

17. The method of claim 16, wherein the ratio of the first metal species, to the sum of the first metal species and the second metal species, varies through a thickness of the multi-metal oxide film.

18. The method of claim 16, wherein, when the multi-metal oxide film is exposed to a hydrogen component, a difference in a thickness of the multi-metal oxide film, before and after being exposed, is 1% or less.

19. The method of claim 16, further comprising applying a power to the first target and to the second target using a single power supply.

20. The method of claim 16, wherein the first target comprises yttrium, and wherein the second target comprises aluminum.

21. The method of claim 16, wherein the multi-metal oxide film comprises an yttrium aluminum oxide film.

22. The method of claim 16, further comprising:
contacting the multi-metal oxide film with a reactive gas comprising a fluorine component sufficient to fluorinate at least a portion of the multi-metal oxide film.

23. The method of claim 16, wherein the substrate is a component of an etch chamber.
